(19) United States
(12) Patent Application Publication
(10) Pub. No.: US 2026/0164739 A1
(43) Pub. Date: Jun. 11, 2026

(54) QUASI-VAN DER WAALS EPITAXIAL HETEROSTRUCTURE, MANUFACTURING METHOD, AND SEMICONDUCTOR DEVICE INCLUDING SAME

(71) Applicants: KOREA ADVANCED INSTITUTE OF SCIENCE AND TECHNOLOGY, Daejeon (KR); TDS Innovation Inc., Daejeon (KR)

(72) Inventors: Ki Bum KANG, Daejeon (KR); Su Hyun KIM, Daejeon (KR)

(21) Appl. No.: 19/410,769

(22) Filed: Dec. 5, 2025

(30) Foreign Application Priority Data
Dec. 6, 2024 (KR) 10-2024-0180634

(51) Int. Cl. H10D 62/82; H10D 30/01; H10D 30/69; H10D 62/10

(52) U.S. Cl. CPC H10D 62/82; H10D 30/017; H10D 30/798; H10D 62/102

(57) ABSTRACT

An embodiment relates to a heterostructure, a heterostructure manufacturing method, and various devices including the same. According to one embodiment, a novel two-dimensional/three-dimensional quasi-van der Waals epitaxy heterostructure in which a three-dimensional material is formed on a two-dimensional material may be described, thereby improving the integration density of existing semiconductor devices and enabling application to various types of semiconductor devices.

### CROSS REFERENCE TO RELATED APPLICATION

The present application claims priority to Korean Patent Application 10-2024-0180634, filed Dec. 6, 2024, in the Korean Intellectual Property Office, the entire contents of which are incorporated here for all purposes by this reference.

### BACKGROUND

The disclosure relates to a heterostructure and a manufacturing method thereof, and more particularly, to a quasi-van der Waals epitaxial heterostructure and a manufacturing method thereof.

Epitaxial growth, a phenomenon in which a oriented crystal film grows on a crystal substrate, has been used as a crystal growth method for device applications. At this time, the substrate serves as a seed crystal upon which new crystals are grown, and these new crystals have the same crystal structure and orientation as the substrate.

Methods for epitaxial growth include chemical vapor deposition (CVD), liquid-phase epitaxy (LPE), and molecular beam epitaxy (MBE) in vacuum.

However, heterogeneous epitaxy, which grows epitaxial layers different from substrates, is limited to two materials with the same lattice structure and a small difference in lattice constants, and mismatches in lattice structure and lattice constants at the growth temperature limit high-quality, defect-free epitaxial growth.

Meanwhile, miniaturization is progressing to improve the integration of semiconductor devices, and research utilizing two-dimensional materials is currently underway. Due to limitations in improving the performance and integration of existing silicon-based semiconductors, new types of materials are being demanded. Thus, transition metal chalcogen compounds, a representative two-dimensional material, are attracting attention as materials with electrical properties that could replace silicon, the traditional semiconductor channel.

### Related Art Document

### Patent Document

(Patent Document 0001) Registered Patent No. 10-1933109

### SUMMARY

An aspect of the disclosure provides a novel heterostructure, a manufacturing method thereof, and a semiconductor device including the same.

The aspect of the disclosure is not limited to that mentioned above, and other aspects not mentioned will be clearly understood by those skilled in the art from the description below.

An embodiment of the disclosure provides a novel heterostructure.

In a heterostructure according to an embodiment of the disclosure in which a three-dimensional material is formed on a two-dimensional material, a van der Waals gap exists at the junction surface, the three-dimensional material grows by quasi-van der Waals epitaxy, and the two-dimensional material and the three-dimensional material have different thermal expansion coefficients or lattice constants.

In an embodiment of the disclosure, in the two-dimensional and three-dimensional materials, atomic arrangement at the interface may form a superlattice structure. A superlattice structure is one in which different lattices overlap to form a new periodic structure.

For example, the superlattice structure may be characterized in that arrangement of the (0001) direction of the two-dimensional material having a trigonal prismatic crystal structure and the (111) direction of the three-dimensional material having a zinc blende crystal structure forms a superlattice.

In an embodiment of the disclosure, the two-dimensional material of the superlattice structure may be one of MoS₂, MoSe₂, MoTe₂, WS₂, WSe₂, and WTe₂, and the three-dimensional material may be one of ZnS, ZnSe, ZnTe, GaN, GaP, GaAs, AlN, InN, AlGaN, and InGaN.

In an embodiment of the disclosure, the heterostructure may be formed on a substrate, and the two-dimensional material and the three-dimensional material may be positioned perpendicular to the substrate and parallel to each other.

In an embodiment of the disclosure, the two-dimensional and three-dimensional materials may include the same chalcogen element.

In an embodiment of the disclosure, the heterostructure may be repeatedly stacked.

In an embodiment of the disclosure, the two-dimensional material may be a metal chalcogen compound.

In an embodiment of the disclosure, the metal chalcogen compound may include: a metal element of groups 3 to 14; and a chalcogen element of group 16.

In an embodiment of the disclosure, the two-dimensional material may include at least one metal element selected from the group consisting of scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), zirconium (Zr), niobium (Nb), molybdenum (Mo), technetium (Tc), ruthenium (Ru), rhodium (Rh), cadmium (Cd), indium (In), tin (Sn), antimony (Sb), tantalum (Ta), tungsten (W), rhenium (Re), iridium (Ir), lead (Pb), hafnium (Hf), and bismuth (Bi), and at least one chalcogen element selected from the group consisting of sulfur(S), selenium (Se), and tellurium (Te).

In an embodiment of the disclosure, the three-dimensional material may be a III-V group compound semiconductor.

In an embodiment of the disclosure, the three-dimensional material may be a II-VI group compound semiconductor.

Another embodiment of the disclosure provides a heterostructure manufacturing method.

A heterostructure manufacturing method according to an embodiment of the disclosure may include: forming a two-dimensional material; and forming a three-dimensional material using a precursor of a three-dimensional metal compound on the two-dimensional material, wherein the two-dimensional material and the three-dimensional material have a van der Waals gap at the junction surface, and different lattice constants and thermal expansion coefficients.

In an embodiment of the disclosure, in the forming of the three-dimensional material, depositing may be performed through a CVD, PVD, ALD or MBE process.

In an embodiment of the disclosure, in the forming of the three-dimensional material, the three-dimensional material may grow by quasi-van der Waals epitaxy.

In an embodiment of the disclosure, the forming of the two-dimensional material and the forming of the three-dimensional material are repeated multiple times.

According to embodiments of the disclosure, a novel type of quasi-van der Waals epitaxy heterostructure can be provided, thereby enhancing the integration density of existing semiconductor devices.

Furthermore, a manufacturing method of the disclosure overcomes the difficulty of epitaxial growth under conditions of lattice constant mismatch or thermal expansion coefficient mismatch, enabling the introduction of a two-dimensional metal compound layer to epitaxially grow a three-dimensional metal chalcogen compound, thereby providing a heterostructure including the same.

The effects of the disclosure are not limited to the effects described above, and should be understood to include all effects that are inferable from the configuration of the disclosure described in the detailed description or claims of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a view illustrating conventional epitaxial growth;

FIG. 2 is a view illustrating (quasi-) van der Waals epitaxial growth;

FIG. 3 is a flowchart schematically illustrating a heterostructure manufacturing method according to an embodiment of the disclosure;

FIGS. 4A-4N are views illustrating devices including a heterostructure according to an embodiment of the disclosure;

FIG. 5 is a view illustrating a heterostructure manufacturing method according to an embodiment of the disclosure;

FIG. 6 is a view illustrating an example of a heterostructure according to an embodiment of the disclosure;

FIG. 7 is a view illustrating SEM and AFM images of a heterostructure according to an embodiment of the disclosure;

FIG. 8 is a view illustrating Raman analysis results of a heterostructure according to an embodiment of the disclosure;

FIG. 9 is a view illustrating TEM analysis results of a heterostructure according to an embodiment of the disclosure;

FIG. 10 is a view illustrating the lattice structure of a heterostructure according to an embodiment of the disclosure;

FIG. 11 is a view showing the results of a (220) plane phi scan of a heterostructure ZnSe layer according to an embodiment of the disclosure;

FIG. 12 is a view showing the results of an analysis of the epitaxial growth pattern of a heterostructure using STEM according to an embodiment of the disclosure;

FIG. 13 is a view showing a heterostructure according to an embodiment of the disclosure;

FIG. 14 is a view showing a heterostructure manufacturing method according to an embodiment of the disclosure;

FIG. 15 is a view showing an SEM image of a heterostructure according to an embodiment of the disclosure;

FIG. 16 is a view showing the results of a Raman analysis of a heterostructure according to an embodiment of the disclosure;

FIG. 17 is a view showing the results of an EDS mapping of a heterostructure according to an embodiment of the disclosure; and

FIG. 18 is a view illustrating the lattice structure of a heterostructure according to an embodiment of the disclosure.

### DETAILED DESCRIPTION

Hereinafter, the disclosure will be described with reference to the accompanying drawings. However, the disclosure may be implemented in various different forms and therefore is not limited to the embodiments described herein. In addition, in order to clearly describe the disclosure in the drawings, parts that are not related to the description are omitted, and similar parts are given similar drawing reference numerals throughout the specification.

In the entire specification, when a part is said to be “connected (linked, contacted, coupled)” to another part, this includes not only the case where it is “directly connected” but also the case where it is “indirectly connected” with another member in between. In addition, when a part is said to “include” a component, this does not mean that it excludes other components, unless otherwise specifically stated, but rather that it may include other components.

The terms used in this specification are used only to describe specific embodiments and are not intended to limit the disclosure. The singular expression includes the plural expression unless the context clearly indicates otherwise. In this specification, the terms “include” or “have” are intended to specify the presence of a feature, number, step, operation, component, part, or combination thereof described in the specification, but should be understood as not excluding in advance the possibility of the presence or addition of one or more other features, numbers, steps, operations, components, parts, or combinations thereof.

Hereinafter, embodiments of the disclosure will be described in detail with reference to the accompanying drawings.

### A Heterostructure According to an Embodiment of the Disclosure Will Be Described

The heterostructure according to an embodiment of the disclosure has a heterostructure structure in which a three-dimensional material is grown on a two-dimensional material.

A van der Waals gap exists at the junction surface of the heterostructure according to an embodiment of the disclosure. In particular, the heterostructure according to the disclosure can have a quasi-van der Waals epitaxial crystal structure between two-dimensional materials and three-dimensional materials, unlike the conventional three-dimensional material-to-three-dimensional material van der Waals epitaxial growth.

Furthermore, the two-dimensional material and the three-dimensional material are characterized by different thermal expansion coefficients and lattice constants.

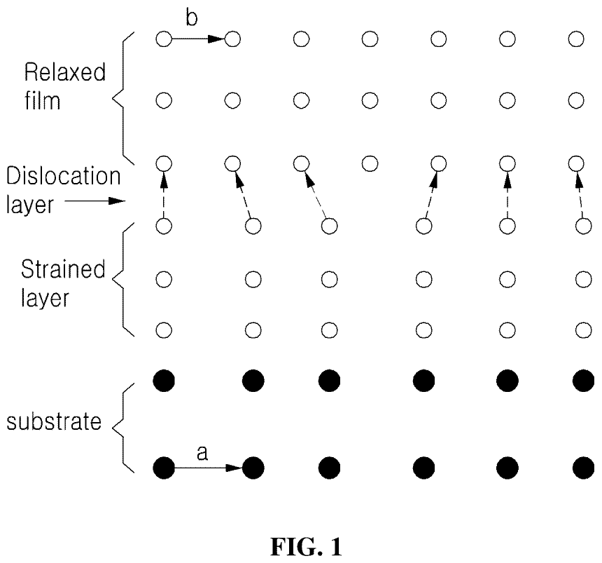

FIG. 1 illustrates conventional epitaxial growth, wherein conventional epitaxial growth means that a single crystal is grown while maintaining the lattice orientation of an underlying seed layer, and additional layers are then stacked.

The lattice constant refers to the distance between atoms forming a covalent bond, wherein when the crystal spacing between the seed layer and the epitaxial layer matches, it is called homo-epitaxy, and when it does not, it is called hetero-epitaxy; conventional epitaxial growth may suffer from defects such as voids if the lattice spacing between atoms within the crystal structure is mismatched, significantly limiting material selection.

Furthermore, previous reports have shown that when the growing epilayer is thick, the difference in thermal expansion coefficients may cause in-plane tensile strain, and thus in addition to the aforementioned lattice mismatch, strain due to differences in thermal expansion coefficients may also significantly impact epitaxial growth.

That is, the van der Waals epitaxial structure of existing 3D-3D materials requires that the lower and upper layers be composed of materials with no or very small differences in lattice constants and thermal expansion coefficients.

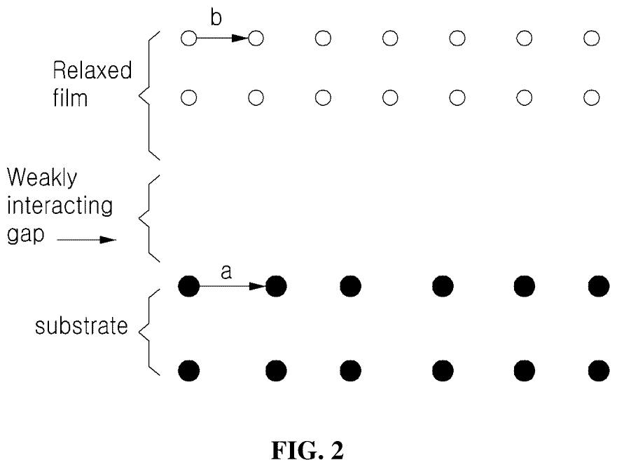

On the other hand, FIG. 2 illustrates quasi-van der Waals epitaxial growth, wherein unlike the conventional epitaxial growth between three-dimensional materials that forms strong bonds, such as covalent bonds between the thin film and the substrate, as shown in FIG. 1, involves two-dimensional materials interacting with relatively weak van der Waals forces with the top or bottom layer, thus enabling them to overcome constraints such as lattice constant mismatch and thermal expansion coefficient mismatch.

At this time, at the interface between the two-dimensional and three-dimensional materials, the atomic arrangements of the two materials may form a superlattice structure. A superlattice structure is one in which different lattices overlap to form a new periodic structure.

According to an embodiment, the superlattice structure may be characterized in that arrangement of the (0001) direction of the two-dimensional material having a trigonal prismatic crystal structure and the (111) direction of the three-dimensional material having a zinc blende crystal structure forms a superlattice.

For example, in the case of the superlattice structure, the two-dimensional material may be one of MoS₂, MoSe₂, MoTe₂, WS₂, WSe₂, WTe₂, which corresponds to an example to be described later, and the three-dimensional material may be one of ZnS, ZnSe, ZnTe. In this case, the (0001) plane of the two-dimensional material and the (111) plane of the three-dimensional material in the heterostructure form a superlattice.

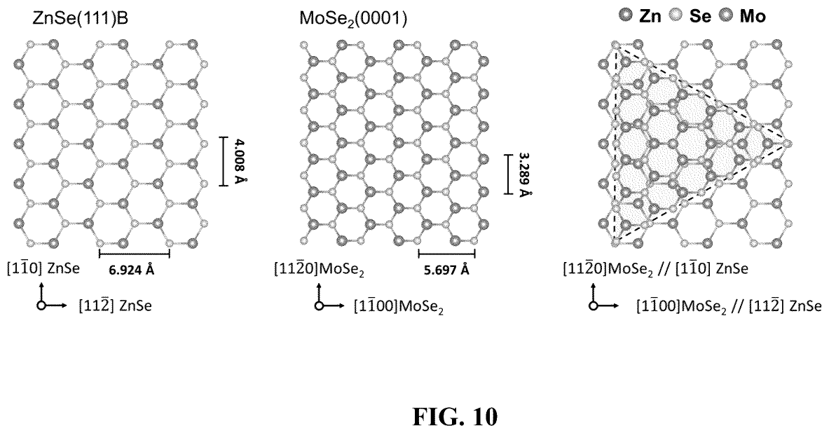

As a specific example, there is a lattice constant mismatch of 17.9% between the atomic arrangement at the (0001) plane of MoSe₂, which has a trigonal prismatic crystal structure, and the atomic arrangement at the (111) plane of ZnSe, which has a zincblende structure. However, as shown in FIG. 10, six units of MoSe₂ unit cells and five units of ZnSe unit cells may form a 6:5 superlattice structure, with a lattice constant mismatch of 1.5%.

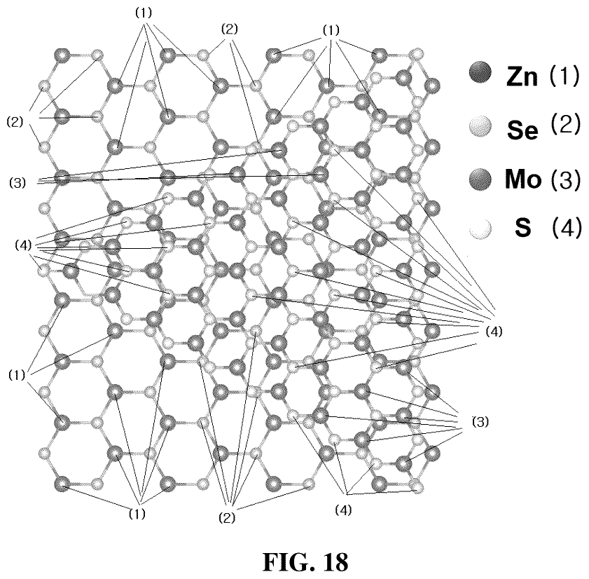

Similarly, as another example, FIG. 18 illustrates the superlattice structure of ZnSe and MoS₂, wherein the atomic arrangement at the (0001) plane of MoS₂, which has a trigonal prismatic crystal structure, and the atomic arrangement at the (111) plane of ZnSe, which has a zincblende structure, have a lattice constant mismatch of 21.4%. However, nine units of MoS₂ unit cells and seven units of ZnSe unit cells may form a 9:7 superlattice structure, with a lattice constant mismatch of 1.3%.

That is, the heterostructure of the disclosure has a three-dimensional material grown on a two-dimensional material having a superlattice structure due to quasi-van der Waals epitaxial growth, despite the lattice constant mismatch.

The heterostructure of the disclosure may be formed on a substrate. At this time, a two-dimensional material may be formed on the substrate, and there is no limitation on the type of substrate, and it may include a material suitable for semiconductor processing. For example, it may refer to various substrates such as silicon, silicon oxide, silicon nitride, gallium nitride, aluminum oxide, aluminum nitride, tantalum, tantalum nitride, copper, ruthenium, titanium nitride, tungsten, and tungsten nitride.

Therefore, a heterostructure may be formed in a stacked manner on a substrate, and the two-dimensional material and the three-dimensional material may be formed perpendicular to the substrate and positioned parallel to each other.

In the heterostructure of the disclosure, the two-dimensional material may include a metal chalcogen compound, graphene, or black phosphorus, and may be preferably a metal chalcogen compound.

At this time, the metal chalcogen compound may include at least one metal element from groups 3 to 14 of the periodic table and at least one chalcogen element from group 16 of the periodic table, and may be a two-dimensional metal chalcogen compound that includes a binary, ternary, or quaternary alloy, preferably a binary, ternary, or quaternary transition metal-chalcogen compound that includes at least one transition metal, and most preferably, a II-VI group compound semiconductor.

For example, the metal element may include at least one selected from the group consisting of scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), zirconium (Zr), niobium (Nb), molybdenum (Mo), technetium (Tc), ruthenium (Ru), rhodium (Rh), cadmium (Cd), indium (In), tin (Sn), antimony (Sb), tantalum (Ta), tungsten (W), rhenium (Re), iridium (Ir), lead (Pb), hafnium (Hf), and bismuth (Bi).

Additionally, the chalcogen element may include at least one selected from the group consisting of sulfur(S), selenium (Se), and tellurium (Te).

For example, the two-dimensional metal chalcogen compound may be a binary metal chalcogen compound represented by MX₂ or MX. M is a metal element selected from groups 3 to 14 of the periodic table, preferably a transition metal element from groups 3 to 12, and X is a chalcogen element selected from group 16 of the periodic table.

For example, the two-dimensional metal chalcogen compound may be a ternary metal chalcogen compound represented by MaX′bXc. M is a metal element selected from groups 3 to 14of the periodic table, preferably a transition metal from groups 3 to 12. X′ and X are different from each other and are chalcogen elements from group 16 of the periodic table, and a, b, and c are rational numbers of 50 or less, and may be appropriately selected to match the oxidation number and/or stoichiometry of the metal in the compound.

For example, the two-dimensional metal chalcogen compound may be a ternary metal-chalcogen compound represented by MaM′bXc. M and M′ are different from each other and are metal elements selected from groups 3 to 14 of the periodic table, preferably transition metal elements from groups 3 to 12. X is a chalcogen element selected from group 16 of the periodic table, and a, b, and c are rational numbers of 50 or less, and may be appropriately selected to match the oxidation number and/or stoichiometry of the metal in the compound.

For example, the two-dimensional metal chalcogen compound may be a quaternary metal-chalcogen compound represented by MaM′bXcX′d. M and M′ are different and are metal elements selected from groups 3 to 14 of the periodic table, preferably transition metal elements from groups 3 to 12. X′ and X are different from each other and are chalcogen elements from group 16 of the periodic table, and a, b, c, and d are rational numbers less than or equal to 50, and may be appropriately selected to match the oxidation number and/or stoichiometry of the metal in the compound.

According to an embodiment of the disclosure, the two-dimensional metal chalcogen compound may include at least one from the group consisting of GaS, GaSe, InS, InSe, FeTe, NiTe₂, CoTe₂, NbS₂, NbSe₂, MoS₂, MoTe₂, MoSe₂, TiS₂, TiSe₂, TiTe₂, ZrS₂, ZrSe₂, PtS₂, PtSe₂, PtTe₂, PdS₂, PdSe₂, PdTe₂, WTe₂, WS₂, WSe₂, WTe₂, SnSe₂, Bi₂Se₃, Bi₂Te₃, MoS₂₍₁₋ₓ₎Se₂ₓ, MoSe_{2(1-l x)}Te₂ₓ, WSe₂₍₁₋ₓ₎Te₂ₓ, WS₂₍₁₋ₓ₎Te₂ₓ, TiSe_{2(1-x )}Te₂ₓ, WTiSe₂, MoWTe₂, MoNbSe₂, TiTaSe₂, MoWSe₂₍₁₋ₓ₎Te₂ₓ, WTiS₂₍₁₋ₓ₎Se₂ₓ, NbS₂₍₁₋ₓ₎Se₂ₓ, NbSe₂₍₁₋ₓ₎Te₂ₓ, TiS₂₍₁₋ₓ₎Se₂ₓ, ReS₂₍₁₋ₓ₎Se₂ₓ, and ReSe₂₍₁₋ₓ₎Te₂ₓ (here, X is a rational number).

For example, the metal element may be molybdenum (Mo), as will be described in an embodiment later. In this case, the precursor of the two-dimensional metal chalcogen compound may include at least one selected from the group consisting of molybdenum hexacarbonyl, ammonium heptamolybdate, molybdenum oxide, molybdenum chloride, molybdenum oxychloride, molybdenum acetylacetonate, molybdenum oxytriethoxide, phosphomolybdic acid, and silicomolybdic acid.

Furthermore, the chalcogen element may be, for example, S, Se, or Te. In this case, the chalcogen precursor may include the chalcogen element, for example, one or more of H₂S, H₂Se, (CH₃)₂S, (C₂H₅)₂S, (CH₃)₂S₂, (CH₃)₂Se, (CH₃)₂Se₂, and (C₂H₅)₂Se.

The two-dimensional material enables quasi-van der Waals epitaxial growth of the three-dimensional material when the two-dimensional layered material is conformally deposited. For example, the two-dimensional material thickness may be 0.6 nm or greater.

In the heterostructure of the disclosure, the three-dimensional material may be quasi-epitaxy grown regardless of the difference in the lattice constant and coefficient of thermal expansion from the two-dimensional material due to the layered structure of the two-dimensional material. Therefore, the three-dimensional material corresponds to a quasi-epitaxy-grown crystalline layer, and according to a preferred example, may be a II-VI compound semiconductor or a III-V compound semiconductor.

For example, the three-dimensional metal compound may be a III-V group compound semiconductor. Specifically, the III-V group compound semiconductor may be represented by M₁X₁, wherein M₁ is at least one selected from the group consisting of Al, Ga, and In, and X₁ is at least one selected from the group consisting of N, P, As, and Sb.

For example, the three-dimensional metal compound may be a II-VI group compound semiconductor. Specifically, the II-VI group compound semiconductor may be represented by M₂X₂, wherein M₂ is at least one element selected from the group consisting of Zn and Cd, and X₂ is at least one chalcogen element selected from the group consisting of O, S, Se, and Te.

Meanwhile, a quasi-van der Waals interface is formed between the two-dimensional material and the three-dimensional material of the disclosure. This corresponds to a configuration distinct from, for example, existing 3D/2D/3D materials, where covalent bonds are formed between the 2D/3D interface through surface treatment or heat treatment, or where, even if a van der Waals interface exists, it follows the crystal structure and polarity of the underlying substrate through remote epitaxy.

Furthermore, the heterostructure of the disclosure may be formed by repeatedly stacking the two-dimensional material and the three-dimensional material.

Next, a heterostructure manufacturing method according to an embodiment of the disclosure will be described.

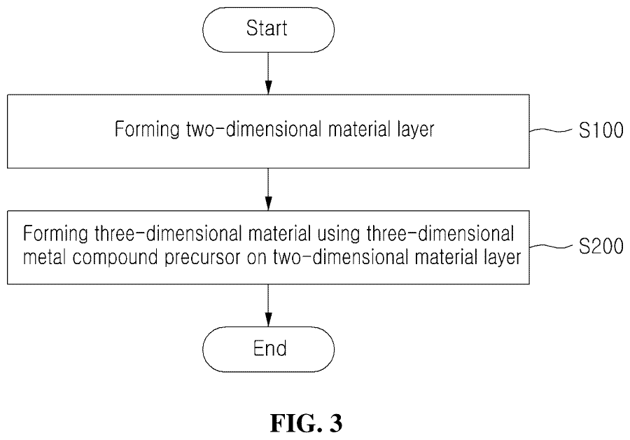

As illustrated in FIG. 3, a heterostructure manufacturing method according to an embodiment of the disclosure includes: forming a two-dimensional material layer (S100); and forming a three-dimensional material using a three-dimensional metal compound precursor on the two-dimensional material layer (S200).

Here, descriptions of portions identical to those described above regarding the heterostructure will be omitted. That is, the two-dimensional material and the three-dimensional material have a van der Waals gap at the junction surface and different lattice constants and coefficients of thermal expansion.

First, a two-dimensional material layer is formed (S100).

The two-dimensional material layer may be formed in the form of a thin film, and the deposition scheme may be any thin film forming scheme commonly employed in the art, such as CVD, PVD, ALD, or MBE.

In this case, Metal Organic Chemical Vapor Deposition (MOCVD) is preferred. MOCVD allows for easy modification of the metal precursors corresponding to the target material, and the supply of high vapor pressure gaseous precursors may be adjusted as needed using a flow adjuster. This allows for precise control of the precursor partial pressures of metal and chalcogen species during the nucleation, domain growth, and lateral growth stages, resulting in high-quality thin films. Furthermore, the ability to uniformly supply gaseous precursors facilitates large-area growth and ensures high reproducibility of the growth process.

For example, this operation may be performed by supplying a chalcogen precursor and a precursor of a two-dimensional metal chalcogen compound onto the substrate, and specifically, when the metal element is molybdenum (Mo) as will be described in an embodiment later, the precursor of the two-dimensional metal chalcogen compound may include at least one selected from the group consisting of molybdenum hexacarbonyl, ammonium heptamolybdate, molybdenum oxide, molybdenum chloride, molybdenum oxychloride, molybdenum acetylacetonate, molybdenum oxytriethoxide, phosphomolybdic acid, and silico molybdic acid.

Additionally, when performing metal-organic chemical vapor deposition, the substrate temperature when depositing the two-dimensional material thin film on the substrate must be appropriately selected, taking into account substrate stability and the temperature at which the synthesized thin film can exist. This temperature may be appropriately set within a range considering the thermal stability of the deposition material. For example, the substrate temperature may range from 100° C. to 1500° C., preferably from 400° C. to 600° C., and most preferably from 500° C.

For example, the chalcogen precursor may be supplied at a flow rate of 0.5 sccm or greater, and the organic precursor of the metal chalcogen compound may be supplied at a flow rate of 3 sccm.

Next, a three-dimensional material is formed on the formed two-dimensional material layer (S200).

As described above, the three-dimensional material may be a group III-V compound semiconductor and may include one or more metals selected from the group consisting of Al, Ga, and In. In this case, the precursor of the three-dimensional material may be trimethylaluminum (Al(CH₃)₃), trimethylgallium (Ga(CH₃)₃), trimethylindium (In(CH₃)₃), etc.

Similarly, as described above, the three-dimensional material may be a group II-VI compound semiconductor and may include at least one metal selected from the group consisting of Zn and Cd. In this case, the precursor of the three-dimensional material may be at least one metal selected from the group consisting of dimethylcadmium (Cd(CH₃)₂), alkylzinc CₙH₂ₙ₊₁)₂Zn (where n is a natural number from 1 to 10), alkylzinc alkoxide, zinc acetate (Zn(OOCCH₃)₂·H₂O), zinc acetate anhydride (Zn(OOCCH₃)₂), and zinc acetylacetonate (Zn(C₅H₇O₂)₂).

Next, other embodiments of the disclosure disclose various devices that include the heterostructure described above.

The heterostructure of the disclosure may be applied to various devices, such as FETs, power semiconductors, spacers, stressors, strain engineering, LEDs, PVs, and sacrificial layers. The devices described below are merely examples of applications for the heterostructure of the disclosure and are not intended to limit the scope of the disclosure.

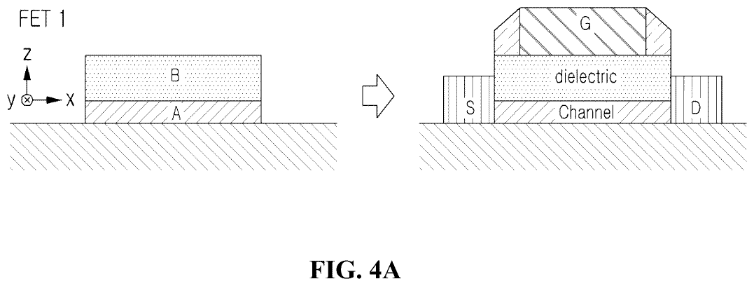

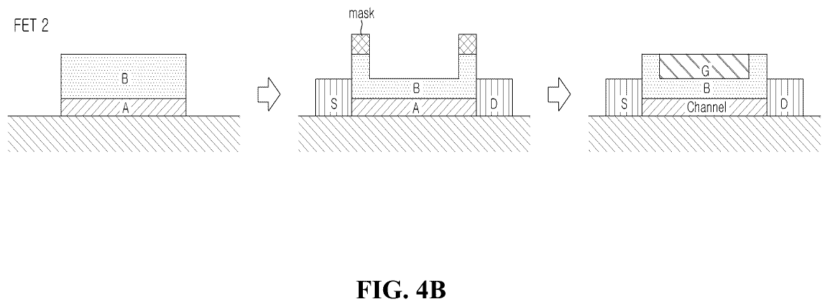

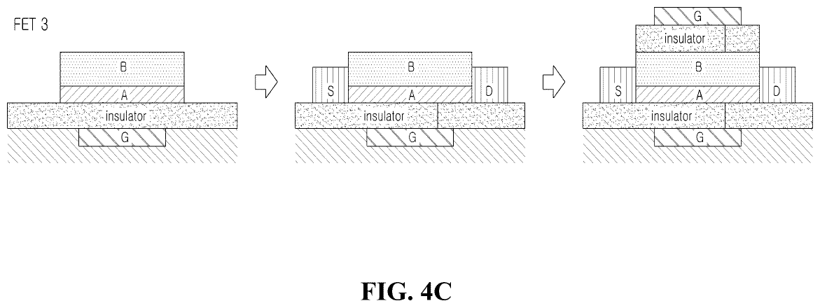

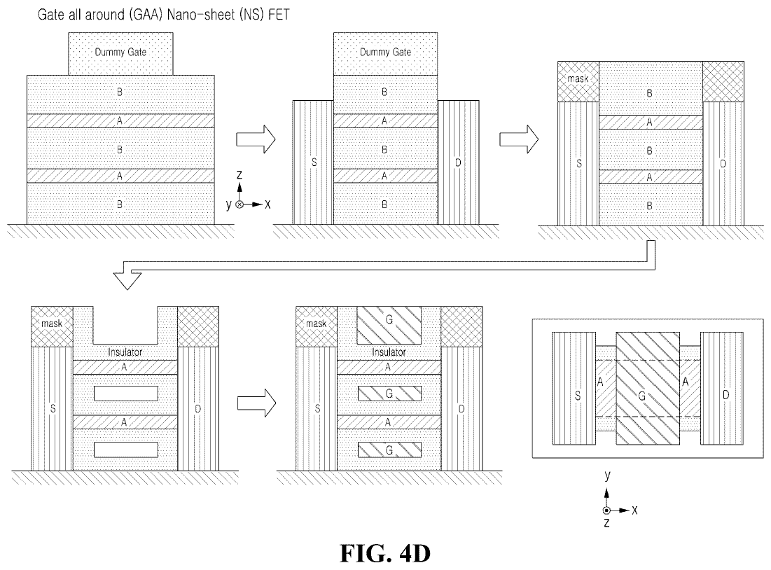

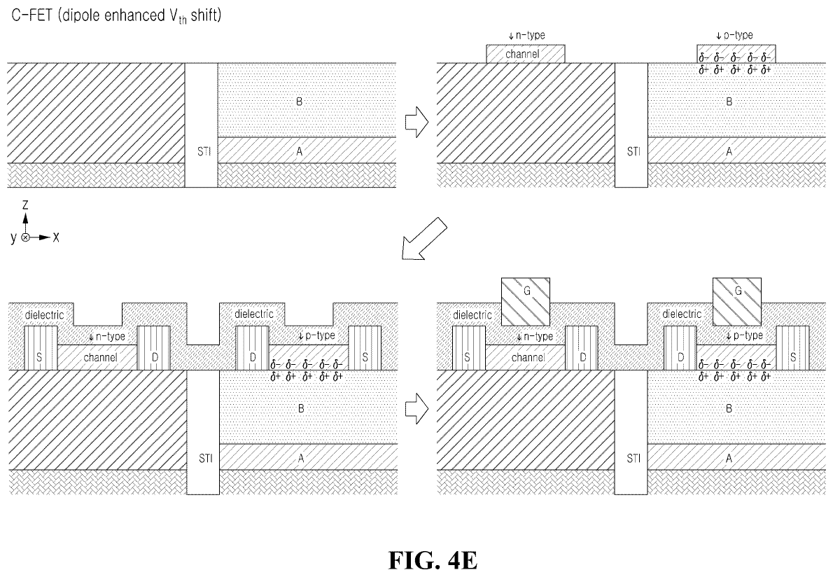

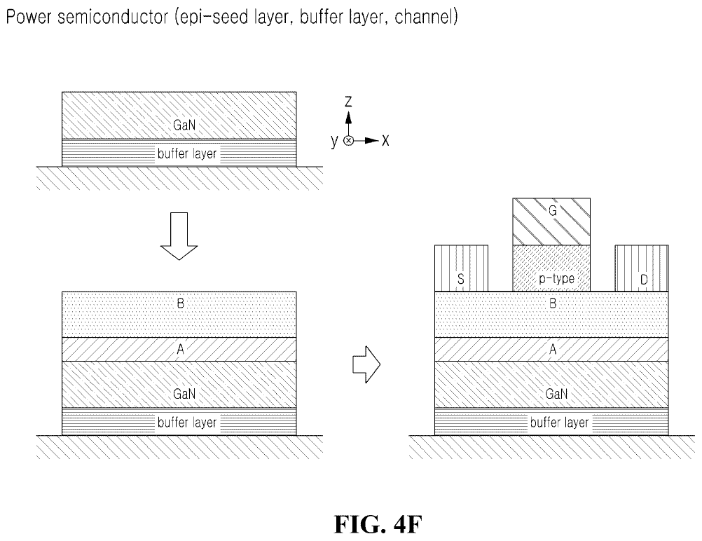

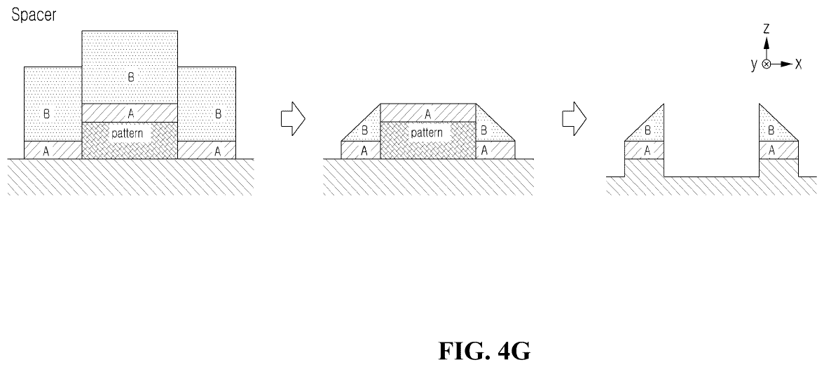

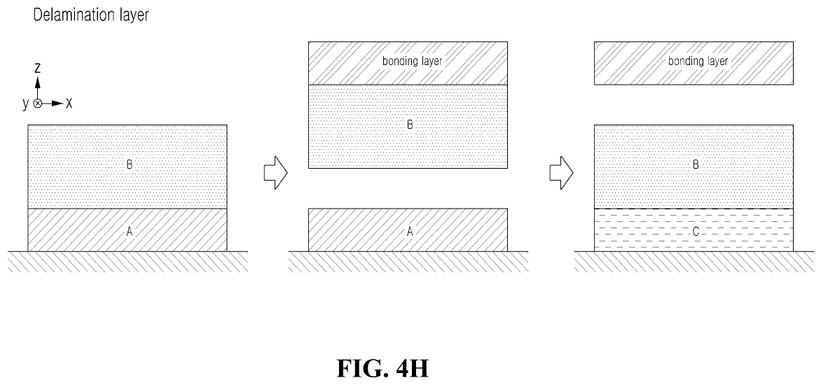

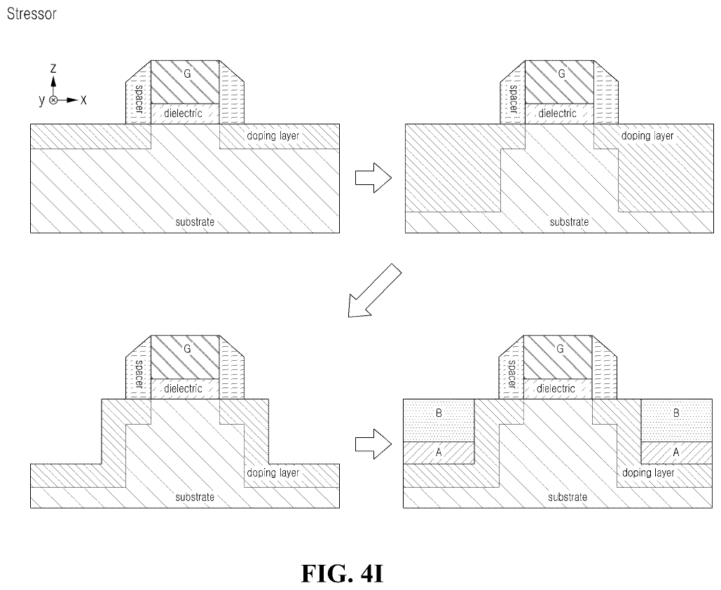

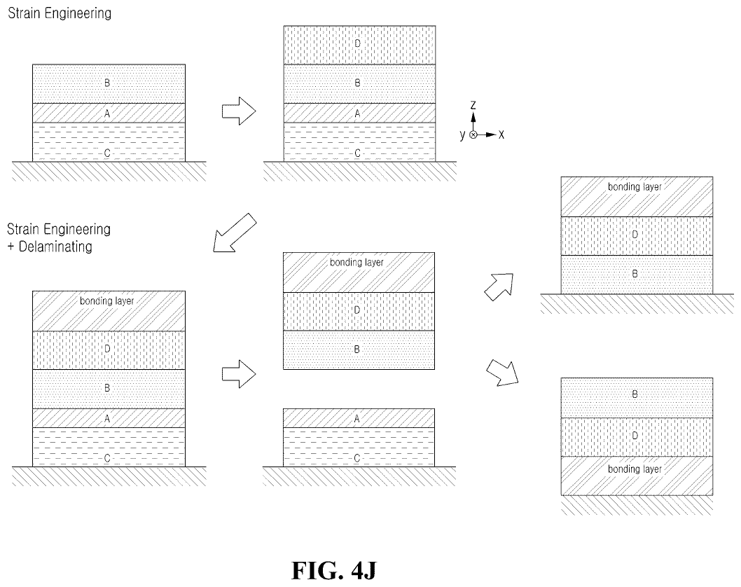

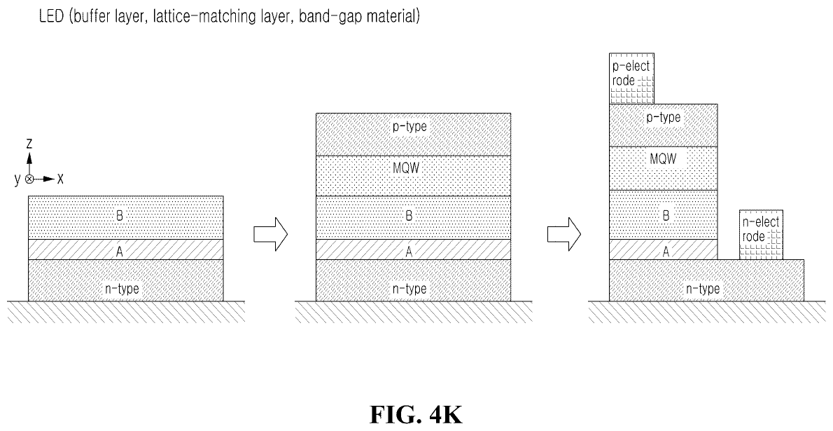

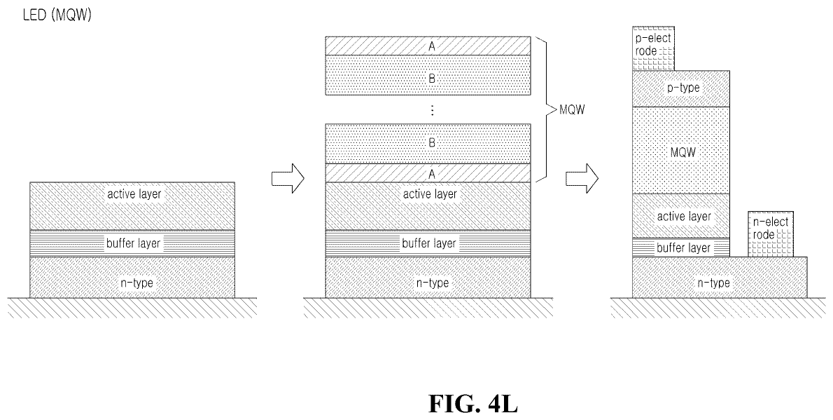

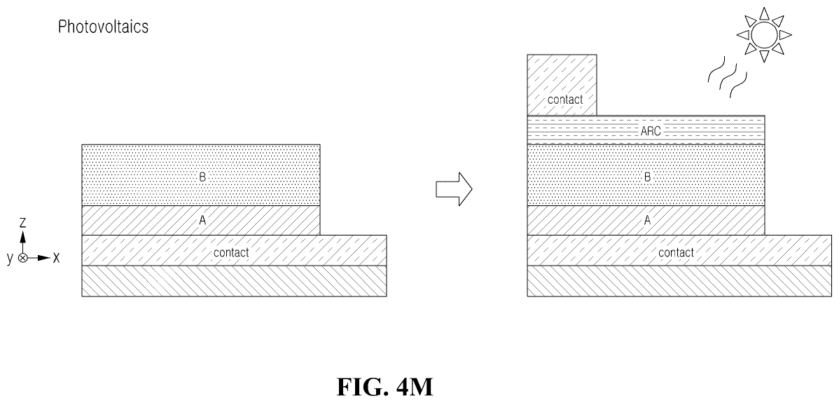

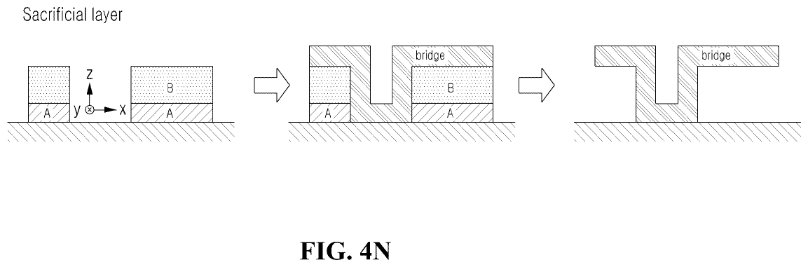

FIG. 4 is a view illustrating devices including a heterostructure according to an embodiment of the disclosure.

Referring to FIGS. 4A to 4N, devices including a heterostructure corresponding to an embodiment of the disclosure, or device manufacturing methods using the same, may be provided. In FIGS. 4A to 4N, the portion indicated by A corresponds to the two-dimensional material of the heterostructure, and the portion indicated by B corresponds to the three-dimensional material of the heterostructure.

Hereinafter, other embodiments of the disclosure will be described in detail with reference to FIG. 4.

FIGS. 4A to 4C illustrate a field effect transistor (FET) semiconductor device including the heterostructure of the disclosure.

FIG. 4A illustrates the heterostructure positioned on a substrate. The two-dimensional material (A) may function as a channel within the semiconductor device. The source (S) and drain (D) contact the side, bottom, top, or one or more thereof of a channel and are spaced apart from each other.

The three-dimensional material (B) within the heterostructure may function as an insulating film. Alternatively, the three-dimensional material may be partially or completely removed using a process such as etching, and an additional operation of depositing an insulating film may be included. A gate (G) is positioned at top of the insulating film (FIG. 4B).

As another example, as shown in FIG. 4C, the two-dimensional material (A) may function as a junction layer or an insulating layer. At this time, the three-dimensional material (B) may function as a channel. The source (S) and drain (D) contact the side, bottom, top, or one or more thereof of a channel and are spaced apart from each other. The gate (G) is positioned at top of the channel, and an insulating film is positioned between the channel and the gate.

Next, FIG. 4D discloses a gate all-around (GAA) nanosheet (NS) FET semiconductor device. As shown in FIG. 4D, the two-dimensional material (A) may function as a channel. In addition, the three-dimensional material (B) may be a sacrificial layer.

Specifically, a heterostructure including one or more two-dimensional material layers is formed on a substrate, and a dummy gate or PR layer, a mask, and a passivation layer are partially formed at the top. Source (S) and drain (D) electrodes are formed by etching along the pattern, and are spaced apart from each other and in contact with the side surfaces of the channel. The three-dimensional material (B), as a sacrificial layer, may be selectively etched to form a gap region. An insulator may be formed on the surface exposed by the gap region. A gate electrode may be formed within the gap region.

Next, FIG. 4E discloses a C-FET semiconductor device. A heterostructure is formed on one side of a region separated by STI on the substrate. One or more heterostructures may be stacked. The three-dimensional material (B) of the heterostructure may function as a dipole layer. A channel formed on a dipole layer may have a different threshold voltage (Vth) value compared to the channel in the other region separated by the STI. Each channel is formed in the STI-separated region, and source and drain electrodes are positioned spaced apart from each other and have surfaces that contact one or more of the side, bottom, or top of the channel. A gate electrode is positioned over the entire or portion of the top of the channel, and an insulating layer is present between the channel and the gate electrode. This Vth shift caused by the dipoles of the three-dimensional material may be utilized to achieve a C-FET semiconductor device.

Next, FIG. 4F discloses a power semiconductor device. The heterostructure may function as an epitaxy seed layer, a buffer layer, or a channel layer. The heterostructure is grown by quasi-van der Waals epitaxy, which is relatively independent of the lattice constant, crystal structure, and polarity of the underlying material. Thus, a material with a different lattice constant, crystal structure, and polarity than the underlying material may be grown at top of the heterostructure as an epitaxy seed layer (not shown). Furthermore, the heterostructure may function as a buffer layer for epitaxial growth of an upper layer with a large lattice constant difference from the underlying material, as it has a different lattice constant than the underlying material (not shown). Furthermore, the two-dimensional material (A) and the three-dimensional material (B) of the heterostructure may function as channels, either individually or simultaneously. For example, a lateral p-GaN HEMT structure including a heterostructure is shown in the drawing. A GaN layer is positioned on the substrate, and a buffer layer may be positioned between the substrate and the GaN layer. A heterostructure is positioned on the GaN layer. B has a wider bandgap than A, and a 2-DEG is formed at the B and A interface. A source, gate, and drain are positioned separately at top of the heterostructure, and a p-GaN layer is positioned between the gate and the heterostructure.

Next, FIG. 4G illustrates a heterostructure spacer. A mask or pattern with a step is positioned on the substrate. The heterostructure is formed on the structure. Another layer or multiple layers may be formed on the heterostructure (not shown). Due to the step at the bottom, a step or a relaxed step is also present in the upper layer. This is etched to form a spacer on the side of the lower mask or pattern. The two-dimensional material (A) within the heterostructure may be an etch stop. The formed spacer may function as a mask for further etching.

Next, FIG. 4H discloses a structure in which the interface between the two-dimensional material (A) and the three-dimensional material (B) of the heterostructure functions as a peel layer. A heterostructure is formed on a substrate. A bonding layer is formed at top of the heterostructure. The bonding layer may be formed through spin coating or deposition, or may be PMMA or thermal tape. A support layer or a support substrate (not shown) may be positioned at top of the bonding layer. When a tensile force is applied in a direction perpendicular to the substrate, peeling occurs at the van der Waals bonding interface between A and B. The peeled portion may be transferred to another layer or substrate. The bonding layer may be removed through chemical selective etching. If the bonding layer is a thermal tape, the bonding layer and the peeling layer may be separated through heating.

Next, FIG. 4I discloses a FET in which the heterostructure functions as a stressor. A gate insulating layer and a gate electrode are positioned on the channel region of the FET. Trenches are formed on one side or opposite sides of the channel region. The area where the trenches are formed may be a doped region. A heterostructure is formed within the trench. The two-dimensional material (A) and three-dimensional material (B) of the heterostructure, as well as the channel material, each have different lattice constants. A layer of the same composition as the channel material may be formed at top of the heterostructure (not shown). The difference in lattice constants between B and the channel material generates tensile or compressive stress in the channel region. The two-dimensional structure may be used as a capping layer for a FET (not shown) and may apply tensile or compressive stress to the channel region of the FET.

Next, FIG. 4J discloses a structure in which a heterostructure is used as a strain engineering layer. The heterostructure is positioned on a substrate. The heterostructure is composed of a two-dimensional material (A) and a three-dimensional material (B). A layer (C) with a different lattice constant from A or B may be positioned between the substrate and the heterostructure. A new material layer (D) may be formed at top of B, and D has a different lattice constant from A, B, or C. Generally, when the lattice constant and coefficient of thermal expansion differ significantly, bonding occurs at the heterojunction surface. However, by using the heterostructure as a strain engineering layer, the difference in lattice constant and coefficient of thermal expansion may be reduced, resulting in the formation of a high-quality film with reduced defects on the heterostructure. The heterostructure may also function as a peel layer, as previously disclosed in FIG. 4H. The layer is peeled off from the van der Waals bonding at the interface between A and B, and the layer, including the strain engineering layer, is placed on another substrate or layer through a transfer process.

Next, FIG. 4K discloses a light-emitting device in which the heterostructure functions as both a buffer layer and an active layer of an LED. An n-type semiconductor layer is formed on a substrate, and the heterostructure composed of the two-dimensional material (A) and the three-dimensional material (B) is formed thereon. A functions as a buffer layer, and B is the active layer. A multi-quantum well (MQW) is formed at top of the heterostructure. The MQW overcomes the differences in lattice constant and coefficient of thermal expansion with the n-type semiconductor layer due to the heterostructure, allowing it to be formed without defects. A p-type semiconductor layer is formed at top of the MQW, and a p-type electrode is formed at a portion of the top. The n-type electrode is formed so that at least one surface is in contact with the underlying n-type semiconductor layer.

Next, FIG. 4L discloses a light-emitting device in which the heterostructure functions as an MQW of an LED. An n-type semiconductor layer is formed on a substrate, and a buffer layer and an active layer are formed thereon. A heterostructure composed of a two-dimensional material (A) and a three-dimensional material (B) is repeatedly formed at top of the active layer to create an MQW. A p-type semiconductor layer is formed at top of the MQW, and a p-type electrode is formed at a portion of the top. The n-type electrode is formed so that at least one surface is in contact with the underlying n-type semiconductor layer. A heterostructure may be used to create a light-emitting device that is independent of the differences in the lattice constant and thermal expansion coefficient of the underlying layer.

Next, FIG. 4M discloses a photovoltaic device in which the heterostructure functions as an active layer. The heterostructure is formed over a lower electrode. A junction layer or buffer layer may be positioned between the lower electrode and the heterostructure (not shown). The two-dimensional material (A) and the three-dimensional material (B) of the heterostructure have different bandgaps and function as the active layer. An antireflection layer (ARC) is positioned over the heterostructure, and an upper electrode is positioned over a portion of the ARC. Light entering through the upper window region is absorbed by the active layer, generating a current.

Next, FIG. 4N discloses a MEMS device in which the heterostructure acts as a sacrificial layer. The heterostructure composed of the two-dimensional material (A) and the three-dimensional material (B) is formed over a substrate. The heterostructure may be etched using a pattern or mask. A new material layer is placed over the patterned heterostructure. The heterostructure is removed through a selective etching process. The new material layer remains unetched, thereby functioning as a bridge structure.

Hereinafter, the disclosure will be described in more detail through a manufacturing example, a comparative example, and an experimental example. However, the disclosure is not limited to the manufacturing example and experimental example described below.

### Experimental Example 1: GaAs/ZnSe/MoSe2 Heterostructure Manufacturing

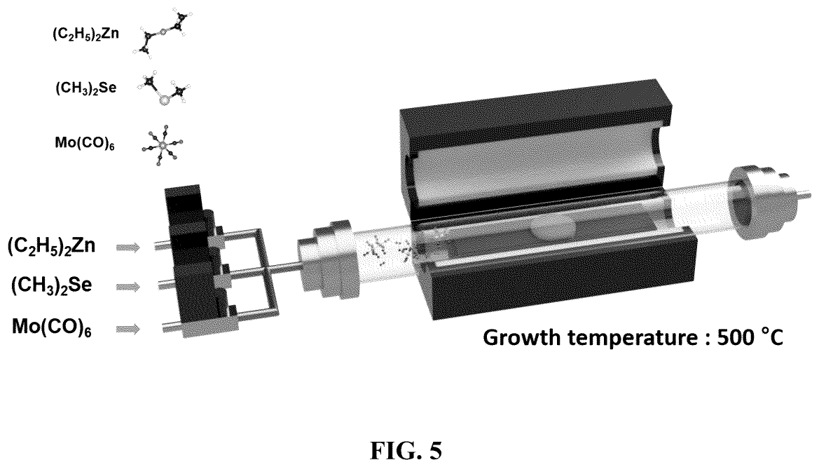

FIG. 5 is a view illustrating a heterostructure manufacturing method according to an embodiment of the disclosure.

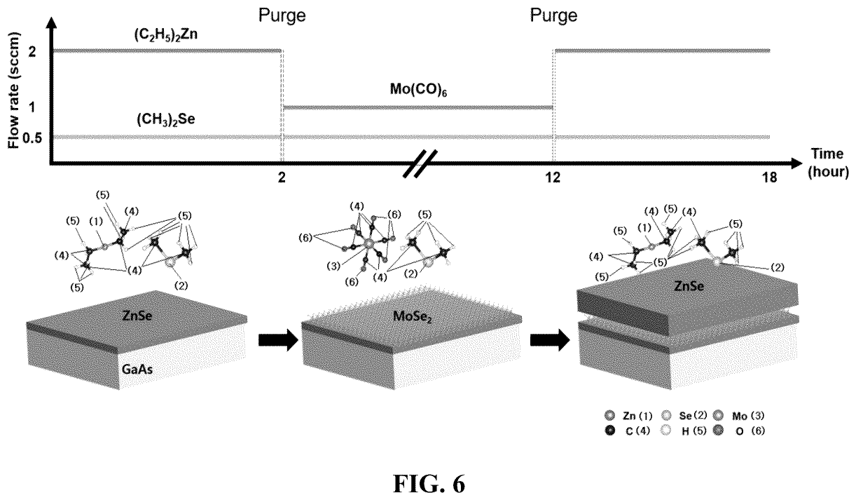

FIG. 6 is a view illustrating an example of a heterostructure according to an embodiment of the disclosure.

As shown in FIG. 5, a high-vapor-pressure organometallic precursor was injected into the gas phase using the MOCVD method. While the flow rate of (CH₃)₂Se was maintained at 0.5 sccm on the GaAs substrate using a flow control device, (C₂H₅)₂Zn was supplied at a flow rate of 2 sccm for 2 hours, and Mo(CO)₆ was supplied at a flow rate of 1 sccm for 10 hours, such that this process changed the metal precursor corresponding to the target material, forming a 2D/3D heterostructure, as shown in FIG. 6. The growth temperature was maintained at 500° C.

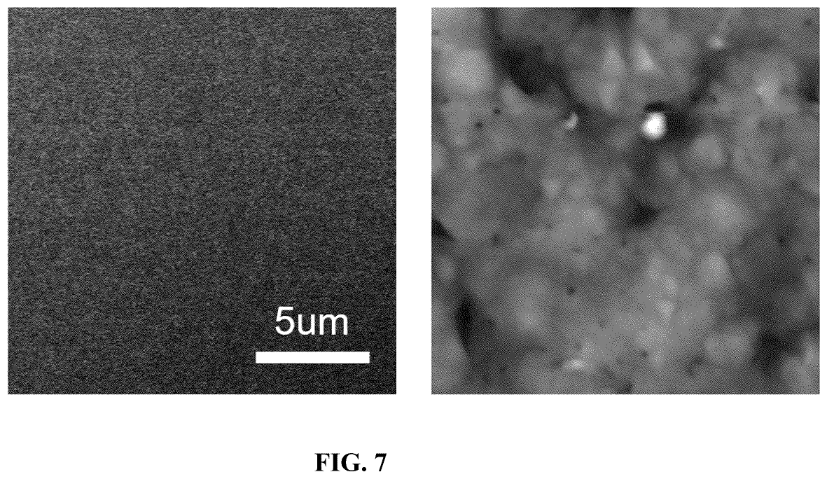

FIG. 7 is a view illustrating SEM and AFM images of a heterostructure according to an embodiment of the disclosure.

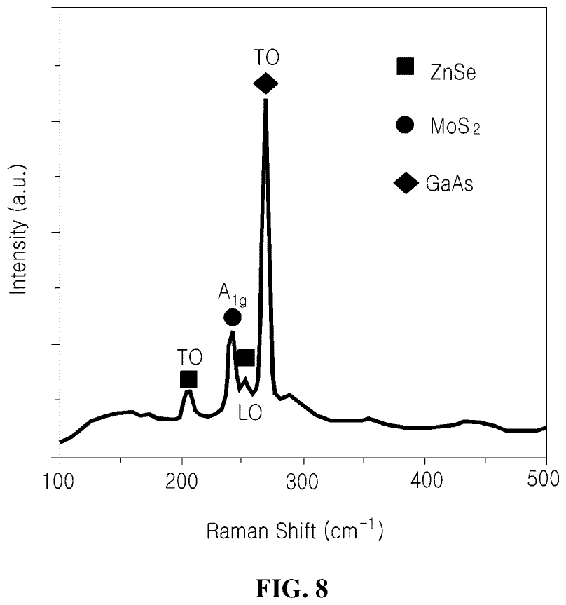

FIG. 8 is a view illustrating Raman analysis results of a heterostructure according to an embodiment of the disclosure.

As shown in FIGS. 7 and 8, it is possible to confirm that a 2D/3D heterostructure thin film was grown using the CVD growth method.

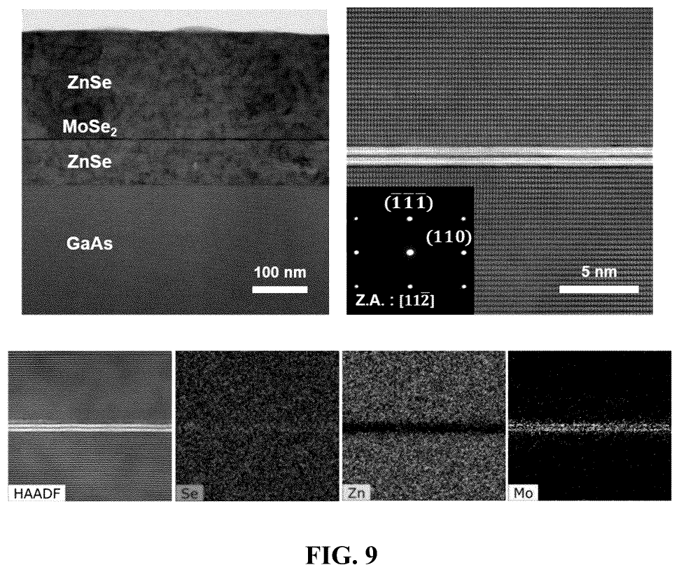

FIG. 9 is a view illustrating TEM analysis results of a heterostructure according to an embodiment of the disclosure.

FIG. 10 is a view illustrating the lattice structure of a heterostructure according to an embodiment of the disclosure.

In FIG. 9, the lattice constant of ZnSe in the [11̅0] direction is 0.4008 nm, and that of MoSe 2 in the [112̅0] direction is 0.3289 nm, wherein the single lattice mismatch in these directions is 17.9%, but, by constructing a superlattice composed of five ZnSe lattices and six MoSe2 lattices, the effective lattice mismatch can be reduced to 1.5%.

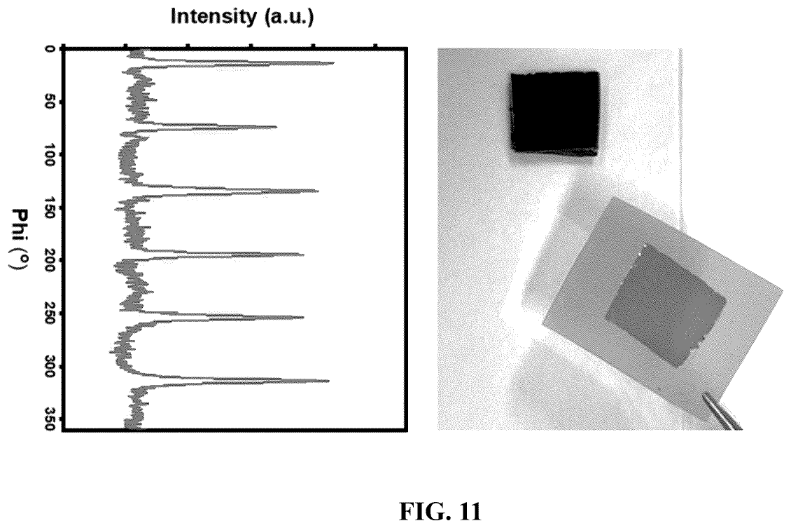

FIG. 11 is a view showing the results of a (220) plane phi scan of a heterostructure ZnSe layer according to an embodiment of the disclosure.

In the phi scan results performed on the ZnSe (220) plane, six peaks were detected at 60°intervals, which confirms that the ZnSe thin film grown on MoSe₂ was quasi-van der Waals epitaxy with in-plane 6-fold symmetry.

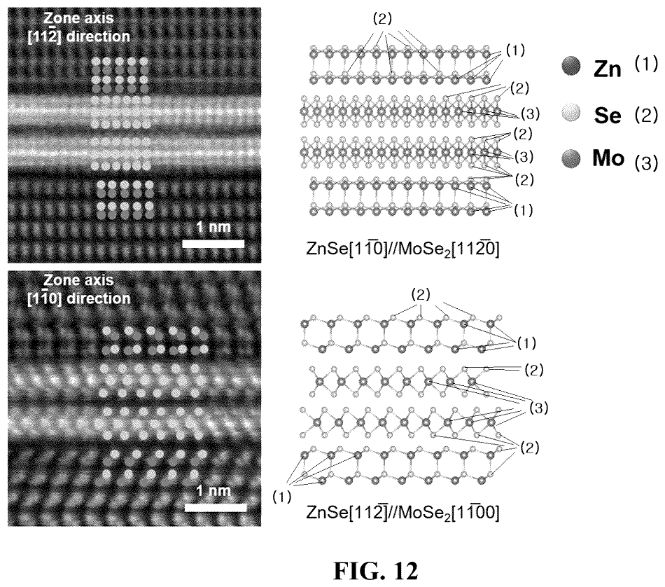

FIG. 12 is a view showing the results of an analysis of the epitaxial growth pattern of a heterostructure using STEM according to an embodiment of the disclosure.

When the interface is observed with the [112̅] zone axis of ZnSe, it is possible to confirm that

the [110] direction of ZnSe and the [112̅0] direction of MoSe₂ are aligned, and when the interface is observed with the [11̅0] zone axis of ZnSe, it is possible to confirm that the [112̅] direction of ZnSe and the [11̅00] direction of MoSe2 are aligned. In the case of conventional epitaxy, the interface elements correspond 1:1 as the epitaxial growth progresses, but in the case of the example, the quasi-van der Waals epitaxial growth pattern can be confirmed in which 5 ZnSe lattices and 6 MoSe₂ lattices correspond periodically, and it can also be confirmed that a van der Waals gap exists at the interface.

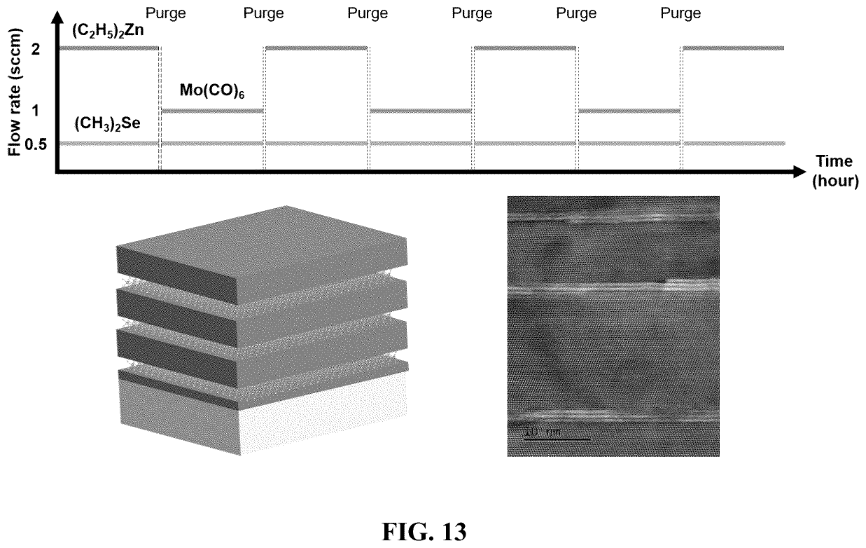

FIG. 13 is a view showing a heterostructure according to an embodiment of the disclosure.

Furthermore, as shown in FIG. 13, by sequentially adjusting the flow rate of the organometallic precursor, a structure including multiple stacked ZnSe and MoSe₂ layers was formed.

The experimental examples described above demonstrate the potential for epitaxial growth free from the constraints of conventional lattice constant mismatch when utilizing two-dimensional materials.

### Experimental Example 2

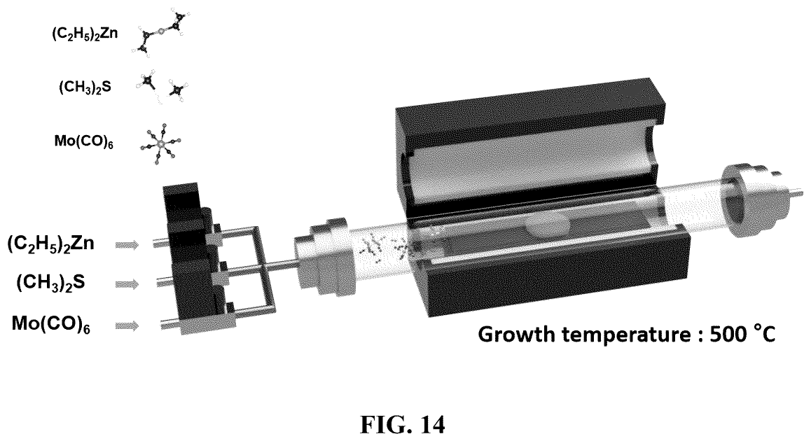

FIG. 14 is a view showing a heterostructure manufacturing method according to an embodiment of the disclosure.

As shown in FIG. 14, a high-vapor-pressure organometallic precursor was injected into the gas phase using the CVD method. While the flow rate of (CH₃)₂S was maintained at 0.5 sccm using a flow control device on a GaAs substrate, (C₂H₅)₂Zn was supplied at a flow rate of 2 sccm for 2 hours and Mo(CO)₆ was supplied at a flow rate of 1 sccm for 10 hours, such that this process changed the metal precursor corresponding to the target material, forming a 2D/3D heterostructure. The growth temperature was maintained at 500° C.

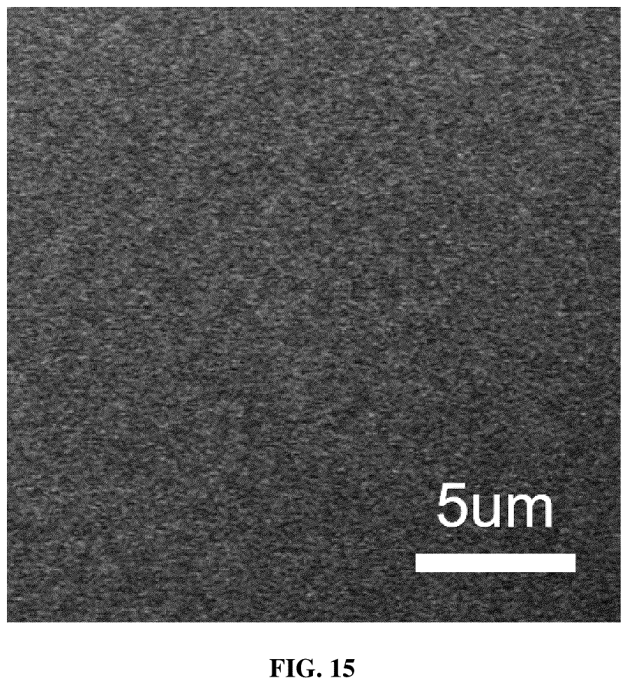

FIG. 15 is a view showing an SEM image of a heterostructure according to an embodiment of the disclosure.

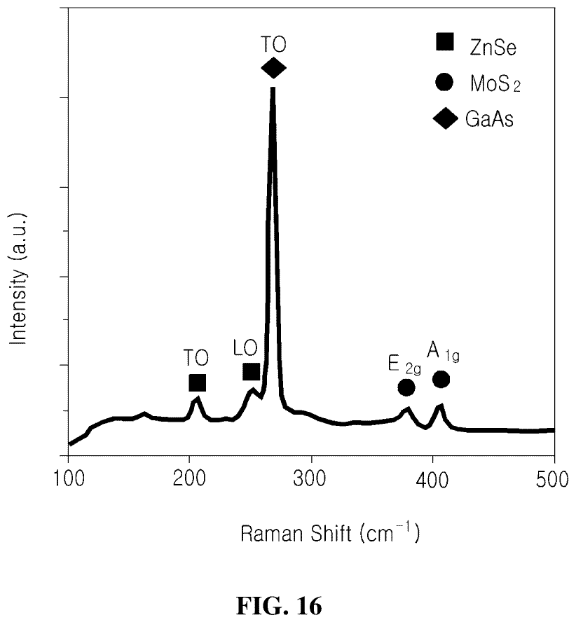

FIG. 16 is a view showing the results of a Raman analysis of a heterostructure according to an embodiment of the disclosure.

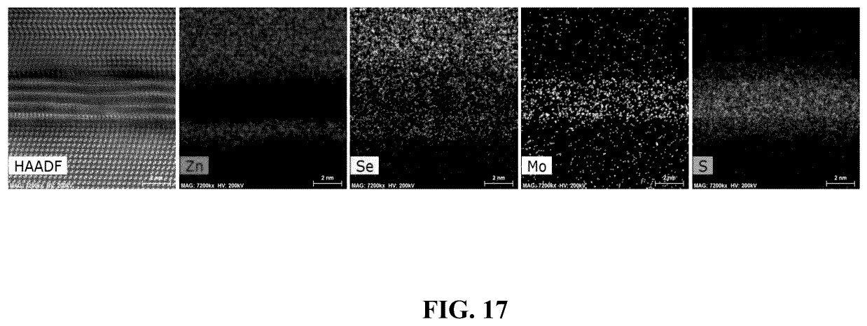

FIG. 17 is a view showing the results of an EDS mapping of a heterostructure according to an embodiment of the disclosure.

FIG. 18 is a view illustrating the lattice structure of a heterostructure according to an embodiment of the disclosure.

The lattice constant of ZnSe in the [11̅0] direction is 0.4008 nm, and that of MoS₂ in the [112̅0] direction is 0.315 nm, wherein the single lattice mismatch in these directions is 21.41%, but, by forming a superlattice composed of seven ZnSe lattices and nine MoS₂ lattices, the effective lattice mismatch can be reduced to 1.3%.

Through the experimental example, it is possible to confirm the possibility of implementing various types of 2D/3D epitaxial heterostructures as well as the above-described experimental example 1.

According to the aforementioned embodiments of the disclosure, the difficulties in epitaxial growth under conditions of lattice constant mismatch or thermal expansion coefficient mismatch can be overcome, providing a heterostructure in which a three-dimensional metal chalcogen compound is epitaxially grown on a two-dimensional metal compound layer.

The description of the disclosure is for illustrative purposes, and those skilled in the art will understand that it can be easily modified into other specific forms without changing the technical idea or essential features of the disclosure. Therefore, the embodiments described above should be understood as being exemplary in all respects and not limiting. For example, each component described as a single type may be implemented in a distributed manner, and likewise, components described as distributed may be implemented in a combined form.

The scope of the disclosure is indicated by the following claims, and all changes or modifications derived from the meaning and scope of the claims and their equivalent concepts should be interpreted as being included in the scope of the disclosure.

What is claimed is:

1. A heterostructure, comprising:
a three-dimensional material defined on a two-dimensional material, wherein a van der Waals gap exists at a junction surface, the three-dimensional material grows by quasi-van der Waals epitaxy, and the two-dimensional material and the three-dimensional material have different thermal expansion coefficients or lattice constants.

2. The heterostructure of claim 1, wherein in the two-dimensional and three-dimensional materials, atomic arrangement at an interface has a superlattice structure.

3. The heterostructure of claim 2, wherein in the superlattice structure, arrangement of a direction of the two-dimensional material having a trigonal prismatic crystal structure and a direction of the three-dimensional material having a zinc blende crystal structure forms a superlattice.

4. The heterostructure of claim 2, wherein the two-dimensional material of the superlattice structure is at least one of MoS₂, MoSe₂, MoTe₂, WS₂, WSe₂, or WTe₂, and the three-dimensional material is at least one of ZnS, ZnSe, ZnTe, GaN, GaP, GaAs, AlN, InN, AlGaN, or InGaN.

5. The heterostructure of claim 1, wherein the heterostructure is defined on a substrate, and the two-dimensional material and the three-dimensional material are disposed perpendicular to the substrate and parallel to each other.

6. The heterostructure of claim 1, wherein the two-dimensional and three-dimensional materials comprise a same chalcogen element.

7. The heterostructure of claim 1, wherein the heterostructure is repeatedly stacked.

8. The heterostructure of claim 1, wherein the two-dimensional material is a metal chalcogen compound.

9. The heterostructure of claim 8, wherein the metal chalcogen compound comprises:
a metal element of Groups 3 to 14; and
a chalcogen element of Group 16.

10. The heterostructure of claim 9, wherein the two-dimensional material comprises at least one metal element selected from a group consisting of scandium (Sc), titanium (Ti), vanadium (V), chromium (Cr), manganese (Mn), iron (Fe), cobalt (Co), nickel (Ni), copper (Cu), zinc (Zn), gallium (Ga), germanium (Ge), zirconium (Zr), niobium (Nb), molybdenum (Mo), technetium (Tc), ruthenium (Ru), rhodium (Rh), cadmium (Cd), indium (In), tin (Sn), antimony (Sb), tantalum (Ta), tungsten (W), rhenium (Re), iridium (Ir), lead (Pb), hafnium (Hf), and bismuth (Bi), and at least one chalcogen element selected from a group consisting of sulfur(S), selenium (Se), and tellurium (Te).

11. The heterostructure of claim 1, wherein the three-dimensional material is a III-V group compound semiconductor.

12. The heterostructure of claim 11, wherein the III-V group compound semiconductor is represented by M₁X₁, where the M₁ is at least one selected from a group consisting of Al, Ga, and In, and the X₁ is at least one selected from a group consisting of N, P, As, and Sb.

13. The heterostructure of claim 1, wherein the three-dimensional material is a II-VI group compound semiconductor.

14. The heterostructure of claim 13, wherein the II-VI group compound semiconductor is represented by M₂X₂, where the M₂ is at least one selected from a group consisting of Zn and Cd, and the X₂ is at least one chalcogen element selected from a group consisting of O, S, Se, and Te.

15. A heterostructure manufacturing method, comprising:
forming a two-dimensional material; and
forming a three-dimensional material using a precursor of a three-dimensional metal compound on the two-dimensional material,
wherein the two-dimensional material and the three-dimensional material have different lattice constants and thermal expansion coefficients, and a van der Waals gap at a junction surface.

16. The heterostructure manufacturing method of claim 15, wherein in the forming the three-dimensional material, depositing is performed through at least one of CVD, PVD, ALD or MBE process.

17. The heterostructure manufacturing method of claim 15, wherein in the forming the three-dimensional material, the three-dimensional material grows by quasi-van der Waals epitaxy.

18. The heterostructure manufacturing method of claim 15, wherein the forming the two-dimensional material and the forming the three-dimensional material are repeated multiple times.

19. A semiconductor device, comprising:
a source;
a drain spaced apart from the source;
the heterostructure of claim 1 disposed in contact between the source and the drain; and
a gate electrode disposed on the heterostructure,
wherein the two-dimensional material or the three-dimensional material of the heterostructure is used as a channel material.

20. The semiconductor device of claim 19, further comprising an insulating layer between the gate electrode and the heterostructure.

21. A semiconductor device, which has the heterostructure of claim 1 used as a dipole engineering layer, the semiconductor device comprising a portion where a shift of a threshold voltage of a channel occurs due to a dipole defined between semiconductor channel and the three-dimensional material.

22. A semiconductor device which has the heterostructure of claim 1 to be used as an epitaxial layer, buffer layer, or channel of a power semiconductor.

23. A semiconductor device which has the heterostructure of claim 1 as a spacer.

24. A semiconductor device manufacturing method which uses the two-dimensional material of the heterostructure of claim 1 as a peeling layer, the method comprising:
forming a bonding layer on the heterostructure; and
applying a force in a direction perpendicular to the heterostructure to cause peeling at the junction surface of the heterostructure, thereby separating the bonding layer with the two-dimensional material of the heterostructure.

25. A semiconductor device which has the heterostructure of claim 1 as a stressor, the semiconductor device comprising:
A trench or bulkhead; and
the heterostructure disposed between trenches or bulkheads,
wherein the three-dimensional material has a lattice constant different from that of a channel material, and
wherein a difference in the lattice constant causes tensile or compressive force to be generated in a channel.

26. A semiconductor device which has the heterostructure of claim 1 as a strain-tuning layer, the semiconductor device comprising:
the heterostructure grown on a substrate; and
an epitaxy layer grown on the heterostructure by epitaxy;
wherein the epitaxy layer has a lattice constant different from that of the three-dimensional material of the heterostructure, and
wherein a difference in the lattice constant between the epitaxy layer and the three-dimensional material is 5% or less.

27. An optical device, comprising:
the heterostructure of claim 1 as a buffer layer; and
a lattice constant tuning layer, or a band gap tuning material.

28. A solar device, comprising the heterostructure of claim 1 as a light absorbing layer.

29. A MEMS device, comprising the heterostructure of claim 1 as a sacrificial layer.
